(19) United States
(12) Patent Application Publication
(10) Pub. No.: US 2004/0096073 A1
(43) Pub. Date: May 20, 2004

(54) Portable multi-channel amplifier

(76) Inventor: Sung Il Kim, Bundang-gu, Seongnam-city (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/415,482

(22) PCT Filed: Nov. 1, 2001
(86) PCT No.: PCT/KR01/01849

(30) Foreign Application Priority Data
Nov. 4, 2000 (KR) 2000/65391

(51) Int. Cl. H03F 21/00

(52) U.S. Cl. 381/120

(57) ABSTRACT

Provided is a portable multi-channel amplifier. The portable multi-channel amplifier includes an input/output adapter and a body. The input/output adapter includes a plurality of cable connectors for connecting an external audio system for reproducing an audio signal, a device for outputting an audio signal as sound via cables, and a circuit connector for connecting the cable connectors to an external circuit. The body includes a connection portion into which the circuit connector of the input/output adapter is inserted and which can be detached from the circuit connector, and a processing circuit for processing the audio signal, which is input from the external audio system through the connection portion, as a multi-channel signal and outputting the multi-channel signal to the outside through the connection portion. A user that carries the portable multi-channel amplifier, which is connected to a portable audio system, can listen to surround stereophonic sound anywhere. Also, in the portable multi-channel amplifier, the body of the portable multi-channel amplifier can be detached from the input/output adapter. Thus, the portable multi-channel amplifier can be conveniently kept and used for many purposes using a docking station at home.

### BACKGROUND OF THE INVENTION

1. Field of the Invention

The present invention relates to an amplifier, and more particularly, to a portable multi-channel amplifier.

2. Description of the Related Art

Amplifiers are classified as separated amplifiers, integrated amplifiers, and receivers. Separated amplifiers include power amplifiers for amplifying sound and transmitting the sound to a speaker and pre-amplifiers for selecting a source. Integrated amplifiers represent amplifiers in which power amplifiers are combined with pre-amplifiers. Receivers represent integrated amplifiers having tuners. The pre-amplifiers are called control amplifiers, which amplify weak signals output from cartridges of microphones or record players, or receive and control signals output from tuners, tape decks, compact disk players, or digital audio tape recorders and transmit the signals to the power amplifiers.

Recently-released amplifiers can produce a sound stage effect for realizing the beauty and reality of audio sound.

The sound stage of an amplifier may be called special sound echoes. Sound is classified as sound that directly comes from musical instruments or speakers and sound that is reflected from other objects scattered around.

The beauty of echoes, i.e., a good or bad sound stage, is determined depending on the directions reflected sound is heard, the materials from which sound is reflected, or how much slower the reflected sound is transmitted compared to direct sound.

In general, a concert hall or theater is designed to be suitable for giving music concerts or showing movies. Thus, a sound stage therefor is usually not poor except in extremely special cases.

However, a residential space is not designed for music or movies. Thus, a sound stage therefor is usually not perfect even if the residential space is equipped with good sound systems.

In particular, the size of a living room is important for the sound stage. In this case, digital signal processors can be used to achieve a good sound stage.

Recently, portable amplifiers having a sound stage effect, which is realized using digital signal processors, and headphones for hearing multi-channel audio signals have been developed.

### SUMMARY OF THE INVENTION

The present invention provides a portable multi-channel amplifier, which has separated input and output terminals, to be conveniently portable and useable using speakers at home.

According to an aspect of the present invention, there is provided a portable multi-channel amplifier. The multi-channel amplifier includes an input/output adapter and a body. The input/output adapter includes a plurality of cable connectors for connecting an external audio system for reproducing an audio signal, a device for outputting an audio signal as sound via cables, and a circuit connector for connecting the cable connectors to an external circuit. The body includes a connection portion into which the circuit connector of the input/output adapter is inserted and which can be detached from the circuit connector, and a processing circuit for processing the audio signal, which is input from the external audio system through the connection portion, as a multi-channel signal and outputting the multi-channel signal to the outside through the connection portion.

The portable multi-channel amplifier further includes a docking station including a connection supporting portion into which the connection portion of the body is inserted to connect a circuit to the connection supporting portion and support the body, and a plurality of cable connectors directly connected to the connection supporting portion to be connected to the external audio system and a speaker system through cables. The body is mounted on the docking station.

The body includes a digital signal processor for receiving an audio signal and converting the audio signal into three-dimensional surround sound having Dolby Pro-Logic, THX, AC-3, or DTS format and a D/A converter for converting a digital signal output from the digital signal processor into an analog signal.

The digital signal processor further has a Dolby Pro-Logic II function which converts 2 channel stereo and 4 channel stereo pro-logic surround into 5.1 channel surround sound.

The digital signal processor further has an Environmental Audio (EAX) function, which is API and used by game developers to make realistic sound effects in games and when caves, waterways, halls, and the like are constituted in games, API is called and related parameters are set for simple sound effects.

The docking station further includes a power amplifier for amplifying a signal output from the body mounted on the docking station and outputting the signal through the cable connectors.

The docking station further includes a voltage supplying means for supplying a voltage to the body through the connection portion of the body.

The docking station includes a charging means for charging the voltage supplied from the voltage supplying means.

The voltage supplying means supplies power using DC-in.

The voltage supplying means supplies power using a USB port.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a portable multi-channel amplifier according to a first embodiment of the present invention;

FIG. 2 is a perspective view of a portable multi-channel amplifier according to a second embodiment of the present invention;

FIG. 3 is a block diagram of the internal structure of the body of a portable multi-channel amplifier according to the present invention; and

FIG. 4 is a perspective view of the body of a portable multi-channel amplifier, which is mounted on a docking station.

### DETAILED DESCRIPTION OF THE INVENTION

Hereinafter, the present invention will be described in detail with reference to the attached drawings.

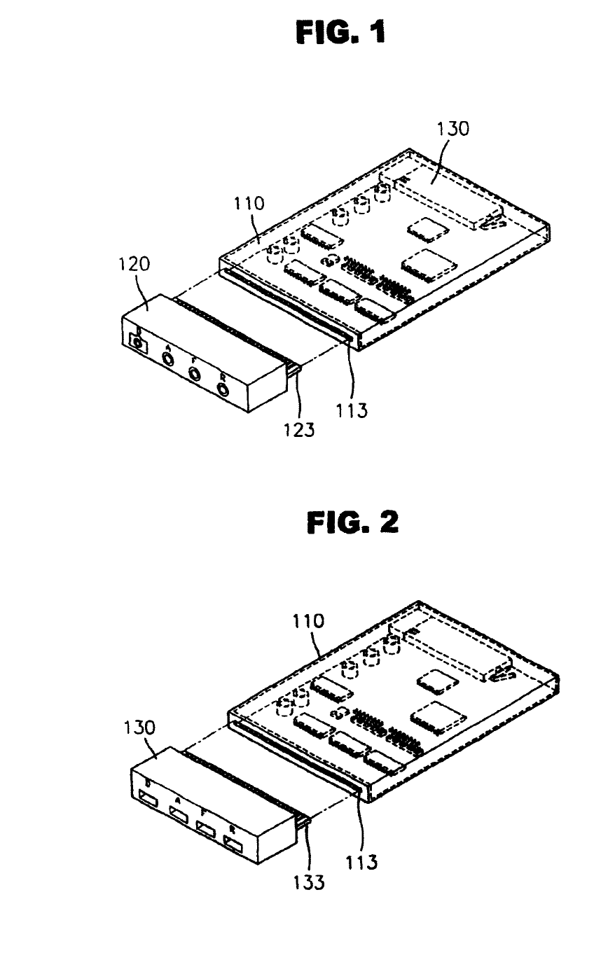

FIG. 1 is a perspective view of a portable multi-channel amplifier according to a first embodiment of the present invention. The portable multi-amplifier includes a body 110 and an input/output adapter 120.

The body 110 amplifies weak signals output from cartridges of microphones or record players, or receives various audio signals output from tuners, tape decks, compact disk players, and digital audio tape recorders and outputs multi-channel signals. The body 110 is manufactured on both sides of a substrate using a digital signal processor (DSP) technique and has a battery 130 therein.

The body 110 includes a connection portion 113 and a processing circuit (not shown). A circuit connector 123 of the input/output adapter 120 is inserted into the connection portion 113. The connection portion 113 can be detached from the connector 123 (133). The processing circuit processes an audio signal, which is input from an external audio system via the connection portion 113, as a multi-channel signal and outputs the multi-channel signal to the outside via the connection portion 113.

The input/output adapter 120, which is coupled to the body 110, includes a plurality of input terminals D and A and a plurality of output terminals F and R. The input terminals D and A receives weak signals output from cartridges of microphones or record players, or receive signals from tuners, tape decks, compact disk players, or digital audio tape recorders. The output terminals F and R output the received signals.

The input/output adapter 120 includes a plurality of cable connectors (i.e., input/output terminals D, A, F, and R) and the circuit connector 123. The cable connectors D, A, F, and R are each connected to cables. The circuit connector 123 connects the cable connectors to an external circuit.

FIG. 2 is a perspective view of a portable multi-channel amplifier according to a second embodiment of the present invention. Referring to FIG. 2, input/output terminals D, A, F, and R of an input/output adapter 130 have a rectangular shape to reduce the size of the input/output adapter 130.

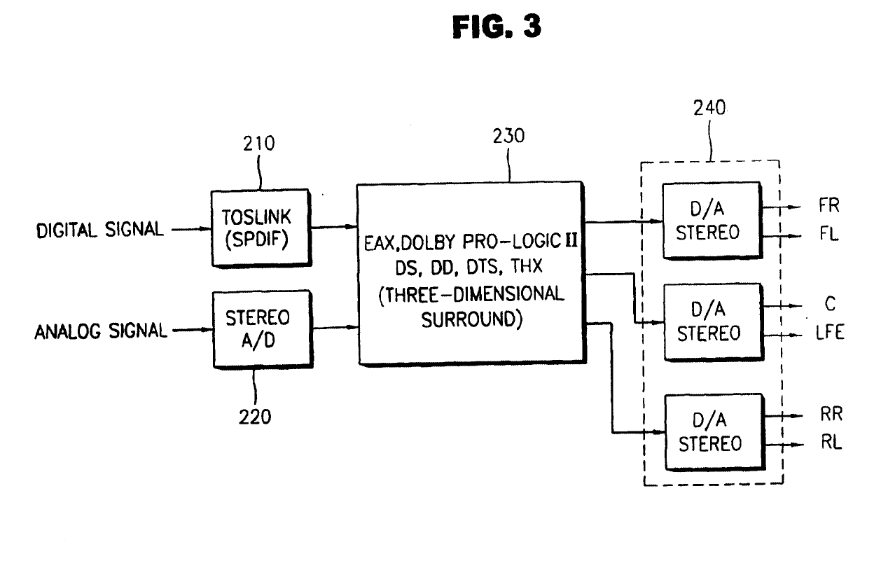

FIG. 3 is a block diagram of the inner structure of the body of a multi-channel amplifier according to the present invention. The body is composed of Toslink 210, which is an optical mini jack and plug device, an analog-to-digital (A/D) converter 220, a digital signal processor 230, and a digital-to-analog (D/A) converter 240.

The Toslink 210 receives a digital signal and transmits the digital signal to the digital signal processor 230.

The A/D converter 220 converts the analog signal into a digital signal and transmits the digital signal to the digital signal processor 230.

The digital signal processor 230 receives the digital signals output from the Toslink 210 and the A/D converter 220 and converts the digital signals into three-dimensional surround sound in such formats as EAX, Dolby Pro-Logic, Dolby Pro-Logic II, THX, AC-3, DS, DD, DTS, and the like.

Environmental Audio (EAX) is application program interface (API), which is used by game developers to make realistic sound effects in games. When caves, waterways, halls, and the like are constituted in games, API is called and related parameters are set for sound effects.

In a game supporting EAX, more realistic sound effects are processed using EAX API. If a game does not support EAX, the game uses EAX preset to indirectly use EAX.

Dolby Pro-Logic is a surround sound format, which is now widespread and found everywhere from general theaters to home videos. The Dolby Pro-Logic format has four signal channels: L, C, R, and surround sound. Since Dolby Pro-Logic is compatible with general stereos, Dolby Pro-Logic is applied to stereo reproducible media.

The Dolby Pro-Logic II is a new 5-channel surround sound system which converts a 2-channel stereo and 4-channel pro-logic surround into 5.1 channel surround sound. The Dolby Pro-Logic II has a movie mode for playing movies and a music mode for playing music.

The movie mode is used for VHS and DVD videos having Dolby Surround microphones and predetermined television programs. The music mode is used for music CDs and other stereo sources.

Dolby Digital (DD) records digital sound to reproduce surround sound of high quality. The DD format may separately record 5.1 channels of sound having low-pass sound effects, divide a full band of 20 Hz-20 KHz into 5.1 channels and store the sounds, and divide 2-channel surround sound into 5.1 channels of sound and store the sounds. Also, the DD reproduces the same dynamic range as in movie theaters and the same remarkable sound stage found in up-to-date movie theaters.

Digital Theater System (DTS) is the newest way of reproducing digital surround sound and has 5.1 channels like DD. However, since the DTS format has a low sound compression ratio, the DTS format can reproduce sound having a highly sensitive signal to noise rate (S/N). The DTS has a wide dynamic range and a good degree of channel separation, i.e., expresses both minute and grand sounds well.

Since DD is the standard format for DVD-Video, all DVD players support DD. However, since the DTS is not the standard format for DVD-video, only some DVD players or exclusive DTS decoding amplifiers can support the DTS.

The distinct difference between DD and DTS is how much audio data can be compressed. DD has a higher compression ratio than DTS. The higher compression ratio means that the original sound source is more damaged. DD has a transmission rate of about 380 kb a second, and DTS has a transmission rate of about 1.4 Mb a second. In other words, DTS transmits about three times more data than DD to reproduce sound similar to DD sound.

THX is not a special sound format standard like DD and DTS. THX, which is made by Lucas Film, is a kind of authentication system applied to sound equipment, image equipment, and sources. THX may be applied to Dolby Pro-Logic, Dolby Digital, and DTS. A DVD title may acquire THX authentication. Products which acquire THX authentication may gain users' confidence in realizing good sound quality and picture quality to some degree.

The D/A converter 240 converts the digital signals output from the digital signal processor 230 into analog signals.

Accordingly, the body 110 produces a sound stage effect for realizing the beauty and reality of audio sound.

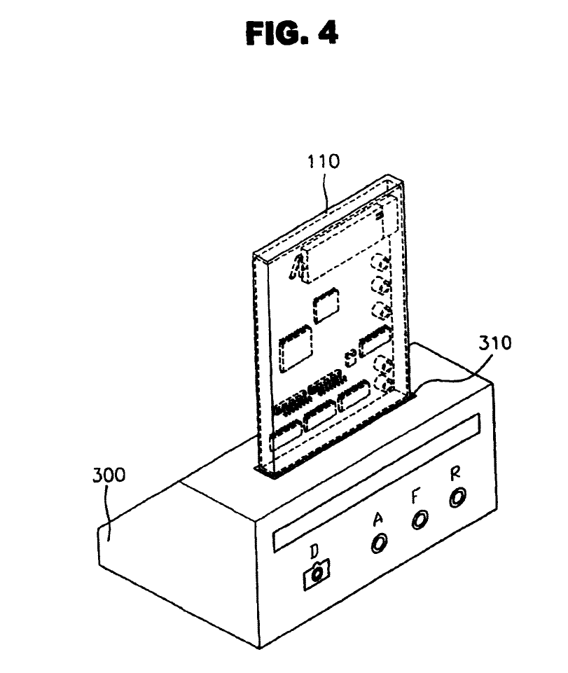

FIG. 4 is a perspective view of the body 110 of a portable multi-channel amplifier, which is mounted on a docking station 300. An external audio system and a speaker system may be connected to the docking station 300 via cables.

The docking station 300 includes a connection supporting portion 310 and a plurality of cable connectors. The connection portion 113 of the body 110 is inserted into the connection supporting portion 310 to connect a circuit to the connection supporting portion 310 and to support the body 110. The plurality of cable connectors are directly connected to the connection supporting portion 310 to be connected to an external audio system and a speaker system via cables.

Also, the docking station 300 includes a power amplifier (not shown), a voltage supplying means (not shown), and a charging means (not shown). The power amplifier amplifies a signal output from the body 110 and outputs the signal through the cable connectors. The voltage supplying means supplies a voltage to the body 110 through the connection portion of the body 110. The charging means charges the voltage supplied from the voltage supplying means. Here, power may be supplied using DC-in and USB ports.

According to the present invention, a user that carries a portable multi-channel amplifier, which is connected to a portable audio system, can listen to surround stereophonic sound anywhere. Also, in the portable multi-channel amplifier, the body of the portable multi-channel amplifier can be detached from an input/output adapter. Thus, the portable multi-channel amplifier can be conveniently kept and used for many purposes using a docking station at home.

Although the invention has been described with reference to embodiments shown in the drawings, the drawings are used for illustration purpose only. The scope of the present invention must not be interpreted as being restricted to the embodiments. Therefore, it will be apparent to one of ordinary skill in the art that modifications to the described embodiment may be made without departing from the spirit and scope of the invention. Consequently, the true technical protective scope of the present invention must be determined based on the technical spirit of the appended claims.

What is claimed is:

1. A portable multi-channel amplifier comprising:
an input/output adapter including a plurality of cable connectors for connecting an external audio system for reproducing an audio signal, a device for outputting an audio signal as sound via cables, and a circuit connector for connecting the cable connectors to an external circuit; and
a body including a connection portion into which the circuit connector of the input/output adapter is inserted and which can be detached from the circuit connector, and a processing circuit for processing the audio signal, which is input from the external audio system through the connection portion, as a multi-channel signal and outputting the multi-channel signal to the outside through the connection portion.

2. The portable multi-channel amplifier of claim 1, further comprising a docking station including a connection supporting portion into which the connection portion of the body is inserted to connect a circuit to the connection supporting portion and support the body, and a plurality of cable connectors directly connected to the connection supporting portion to be connected to the external audio system and a speaker system through cables, wherein the body is mounted on the docking station.

3. The portable multi-channel amplifier of claim 1, wherein the body comprises:
a digital signal processor for receiving an audio signal and converting the audio signal into three-dimensional surround sound having Dolby Pro-Logic, THX, AC-3, or DTS format; and
a D/A converter for converting a digital signal output from the digital signal processor into an analog signal.

4. The portable multi-channel amplifier of claim 3, wherein the digital signal processor further has a Dolby Pro-Logic II function which converts 2 channel stereo and 4 channel stereo pro-logic surround into 5.1 channel surround sound.

5. The portable multi-channel amplifier of claim 3, wherein the digital signal processor further has an Environmental Audio (EAX) function, which is API and used by game developers to make realistic sound effects in games and when caves, waterways, halls, and the like are constituted in games, API is called and related parameters are set for simple sound effects.

6. The portable multi-channel amplifier of claim 2, wherein the docking station further comprises a power amplifier for amplifying a signal output from the body mounted on the docking station and outputting the signal through the cable connectors.

7. The portable multi-channel amplifier of claim 6, wherein the docking station further comprises a voltage supplying means for supplying a voltage to the body through the connection portion of the body.

8. The portable multi-channel amplifier of claim 7, wherein the docking station comprises a charging means for charging the voltage supplied from the voltage supplying means.

9. The portable multi-channel amplifier of claim 8, wherein the voltage supplying means supplies power using DC-in.

10. The portable multi-channel amplifier of claim 8, wherein the voltage supplying means supplies power using a USB port.
